(19) United States
(12) Patent Application Publication
(10) Pub. No.: US 2026/0150187 A1
(43) Pub. Date: May 28, 2026

(54) PRINTED WIRING BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Kousuke MIURA, Osaka (JP); Koji NITTA, Osaka (JP); Shoichiro SAKAI, Osaka (JP); Yoshio OKA, Osaka (JP); Takashi KASUGA, Shiga (JP); Yoshihito YAMAGUCHI, Shiga (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 19/121,659

(22) PCT Filed: Oct. 6, 2023
(86) PCT No.: PCT/JP2023/036476

§ 371 Date: Apr. 16, 2025

(30) Foreign Application Priority Data
Oct. 20, 2022 (JP) 2022-168266

(51) Int. Cl. H05K 1/02; H05K 1/11; H05K 3/18

(52) U.S. Cl. CPC H05K 1/0298; H05K 1/115; H05K 3/188

(57) ABSTRACT

A printed wiring board includes an insulating layer having a first main surface and a second main surface, a first copper layer disposed on the first main surface, a second copper layer disposed on the second main surface; and a third copper layer. A through-hole reaching the second copper layer is formed in the insulating layer and the first copper layer, the third copper layer is disposed on the second copper layer inside the through-hole, on an inner wall surface of the through-hole, and on the first copper layer located around the through-hole, a single copper layer is disposed on the inner wall surface of the through-hole, and the single copper layer is the third copper layer.

### TECHNICAL FIELD

The present disclosure relates to a printed wiring board. The present application claims priority based on Japanese Patent Application No. 2022-168266 filed on Oct. 20, 2022, and the entire contents of the Japanese patent application are incorporated herein by reference.

### BACKGROUND ART

Japanese Unexamined Patent Application Publication No. 2017-037990 (PTL 1) discloses a printed wiring board. The printed wiring board disclosed in PTL 1 includes an inner-layer resin layer, an inner-layer circuit, an organic adhesion layer, an organic insulating resin layer, an outer-layer copper layer, and an outer-layer circuit.

The inner-layer resin layer has a first main surface. The inner-layer circuit is disposed on the first main surface. The organic adhesion layer is disposed on the first main surface so as to cover the inner-layer circuit. The organic insulating resin layer has a second main surface and a third main surface. The third main surface is a surface opposite to the second main surface. The organic insulating resin layer is disposed on the organic adhesion layer such that the second main surface faces the organic adhesion layer. A through-hole from which the inner-layer circuit is exposed is formed in the organic adhesion layer and the organic insulating resin layer.

The outer-layer copper layer is a copper layer formed by electroless plating. The outer-layer copper layer is disposed on the inner-layer circuit exposed from the through-hole, on the inner wall surface of the through-hole, and on the third main surface around the though-hole. The outer-layer circuit is a copper layer formed by electroplating. The outer-layer circuit is disposed on the outer-layer copper layer. In the printed wiring board disclosed in PTL 1, the outer-layer circuit and the inner-layer circuit are electrically connected to each other in this manner.

### CITATION LIST

### Patent Literature

PTL 1: Japanese Unexamined Patent Application Publication No. 2017-037990

### SUMMARY OF INVENTION

A printed wiring board according to the present disclosure includes an insulating layer having a first main surface and a second main surface, a first copper layer disposed on the first main surface, a second copper layer disposed on the second main surface, and a third copper layer, in which a through-hole reaching the second copper layer is formed in the insulating layer and the first copper layer, the third copper layer is disposed on the second copper layer inside the through-hole, on an inner wall surface of the through-hole, and on the first copper layer located around the through-hole, a single copper layer is disposed on the inner wall surface of the through-hole, and the single copper layer is the third copper layer.

### BRIEF DESCRIPTION OF DRAWINGS

FIG. 1 is a sectional view of a printed wiring board 100.

FIG. 2 is a flowchart illustrating a process of manufacturing a printed wiring board 100.

FIG. 3 is a sectional view illustrating a preparation step S1.

FIG. 4 is a sectional view illustrating a first etching step S2.

FIG. 5 is a sectional view illustrating a hole forming step S3.

FIG. 6 is a sectional view illustrating a resist pattern forming step S5.

FIG. 7 is a sectional view illustrating an electroplating step S6.

FIG. 8 is a sectional view illustrating a resist pattern removing step S7.

FIG. 9 is a sectional view of a printed wiring board 100A.

FIG. 10 is a sectional view of a printed wiring board 200.

FIG. 11 is a flowchart illustrating a process of manufacturing a printed wiring board 200.

FIG. 12 is a sectional view illustrating a preparation step S11.

FIG. 13 is a sectional view illustrating a first hole forming step S12.

FIG. 14 is a sectional view illustrating a first resist pattern forming step S13.

FIG. 15 is a sectional view illustrating a first electroplating step S14.

FIG. 16 is a sectional view illustrating a first resist pattern removing step S15.

FIG. 17 is a sectional view illustrating a first etching step S16.

FIG. 18 is a sectional view illustrating an insulating layer attaching step S17.

FIG. 19 is a sectional view illustrating a second hole forming step S18.

FIG. 20 is a sectional view illustrating a second resist pattern forming step S19.

FIG. 21 is a sectional view illustrating a second electroplating step S20.

FIG. 22 is a sectional view illustrating a second resist pattern removing step S21.

### DETAILED DESCRIPTION

### Problems to be Solved by Present Disclosure

In the printed wiring board disclosed in PTL 1, when the outer-layer copper layer is formed by electroless plating, palladium is used as a catalyst. Therefore, palladium may remain at the interface between the inner-layer circuit and the outer-layer copper layer. The palladium remaining between the inner-layer circuit and the outer-layer copper layer may cause the separation of the outer-layer circuit from the inner-layer circuit together with the outer-layer copper layer due to, for example, thermal shock, resulting in disconnection.

In the printed wiring board disclosed in PTL 1, before the outer-layer copper layer is formed by electroless plating, etching may be performed in order to remove foreign matter and an oxide film (hereinafter, abbreviated as foreign matter and the like) present on the surface of the inner-layer circuit. This etching has to be a mild process in order to avoid excessive erosion of the inner-layer circuit, and thus foreign matter and the like remain on the surface of the inner-layer circuit. The foreign matter and the like remaining on the surface of the inner-layer circuit may decrease adhesiveness between the inner-layer circuit and the outer-layer copper layer and cause the separation of the outer-layer circuit from the inner-layer circuit together with the outer-layer copper layer, resulting in disconnection.

The present disclosure has been made in view of the above-described problems in the related art. More specifically, the present disclosure provides a printed wiring board in which the occurrence of disconnection in a blind via hole can be reduced. The blind via hole refers to a hole through which an outermost circuit and one or more inner-layer circuits of a printed wiring board are electrically or physically connected together by copper plating or the like. The hole of the blind via hole does not extend to an outermost circuit on the opposite side.

### Advantageous Effects of Present Disclosure

According to the printed wiring board according to the present disclosure, the occurrence of disconnection in a blind via hole can be reduced.

### DESCRIPTION OF EMBODIMENTS OF PRESENT DISCLOSURE

First, embodiments of the present disclosure will be listed and described.
(1) A printed wiring board according to an embodiment includes an insulating layer having a first main surface and a second main surface, a first copper layer disposed on the first main surface, a second copper layer disposed on the second main surface, and a third copper layer, in which a through-hole reaching the second copper layer is formed in the insulating layer and the first copper layer, the third copper layer is disposed on the second copper layer inside the through-hole, on an inner wall surface of the through-hole, and on the first copper layer located around the through-hole, a single copper layer is disposed on the inner wall surface of the through-hole, and the single copper layer is the third copper layer.

According to the printed wiring board of (1) above, the occurrence of disconnection in a blind via hole can be reduced.
(2) In the printed wiring board of (1) above, a thickness of the third copper layer on the first copper layer may be equal to or more than 0.4 times a thickness of the insulating layer and may be equal to or less than 0.6 times a minimum value of a width of the through-hole at the first main surface.

According to the printed wiring board of (2) above, the third copper layer formed on the first copper layer located around the through-hole and the third copper layer formed on the second copper layer exposed from the through-hole can be easily connected to each other.
(3) In the printed wiring board of (1) above, a thickness of the third copper layer on the first copper layer may be equal to or more than 0.8 times a thickness of the insulating layer and may be equal to or less than 0.45 times a minimum value of a width of the through-hole at the first main surface.

According to the printed wiring board of (3) above, the third copper layer formed on the first copper layer located around the through-hole and the third copper layer formed on the second copper layer exposed from the through-hole can be more easily connected to each other.
(4) In the printed wiring board of any one of (1) to (3) above, palladium concentrations in a region of the third copper layer from an interface between the insulating layer and the third copper layer to a depth of 10 nm and a region of the third copper layer from an interface between the second copper layer and the third copper layer to a depth of 10 nm may each be 0.5% by mass or less.
(5) In the printed wiring board of any one of (1) to (4) above, the third copper layer may be a copper electroplating layer.
(6) A printed wiring board according to an embodiment includes a first insulating layer having a first main surface, a first copper layer disposed on the first main surface, an adhesion layer disposed on the first main surface so as to cover the first copper layer, a second insulating layer having a second main surface and a third main surface and disposed on the adhesion layer such that the second main surface faces the adhesion layer, a second copper layer disposed on the third main surface, and a third copper layer, in which a through-hole reaching the first copper layer is formed in the second insulating layer, the second copper layer, and the adhesion layer, the third copper layer is disposed on the first copper layer inside the through-hole, on an inner wall surface of the through-hole, and on the second copper layer located around the through-hole, a single copper layer is disposed on the inner wall surface of the through-hole, and the single copper layer is the third copper layer.

According to the printed wiring board of (6) above, the occurrence of disconnection in a blind via hole can be reduced.
(7) In the printed wiring board of (6) above, a thickness of the third copper layer on the second copper layer may be equal to or more than 0.4 times a sum of a thickness of the second insulating layer and a thickness of the adhesion layer located between the first copper layer and the second insulating layer and may be equal to or less than 0.6 times a minimum value of a width of the through-hole at the third main surface.

According to the printed wiring board of (7) above, the third copper layer formed on the second copper layer located around the through-hole and the third copper layer formed on the first copper layer exposed from the through-hole can be easily connected to each other.
(8) In the printed wiring board of (6) above, a thickness of the third copper layer on the second copper layer may be equal to or more than 0.8 times a sum of a thickness of the second insulating layer and a thickness of the adhesion layer located between the first copper layer and the second insulating layer and may be equal to or less than 0.45 times a minimum value of a width of the through-hole at the third main surface.

According to the printed wiring board of (8) above, the third copper layer formed on the second copper layer located around the through-hole and the third copper layer formed on the first copper layer exposed from the through-hole can be more easily connected to each other.
(9) In the printed wiring board of any one of (6) to (8) above, palladium concentrations in a region of the third copper layer from an interface between the second insulating layer and the third copper layer to a depth of 10 nm and a region of the third copper layer from an interface between the first copper layer and the third copper layer to a depth of 10 nm may each be 0.5% by mass or less.
(10) In the printed wiring board of any one of (6) to (9) above, the third copper layer may be a copper electroplating layer.

### DETAILS OF EMBODIMENTS OF PRESENT DISCLOSURE

Details of embodiments of the present disclosure will be described with reference to the drawings. In the drawings, the same or equivalent parts are assigned the same reference signs, and duplicate descriptions are not repeated.

### First Embodiment

A printed wiring board according to a first embodiment will be described. The printed wiring board according to the first embodiment is referred to as a printed wiring board 100.

### <Configuration of Printed Wiring Board 100>

The configuration of the printed wiring board 100 will be described below.

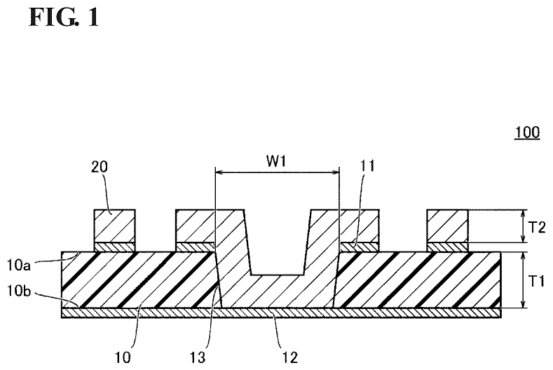

FIG. 1 is a sectional view of the printed wiring board 100. As illustrated in FIG. 1, the printed wiring board 100 includes an insulating layer 10, a first copper layer 11, a second copper layer 12, and a third copper layer 20.

The constituent material of the insulating layer 10 has electrical insulating properties and flexibility. The constituent material of the insulating layer 10 is, for example, a polyimide. However, the constituent material of the insulating layer 10 is not limited to this. The insulating layer 10 has a first main surface 10a and a second main surface 10b. The first main surface 10a and the second main surface 10b are surfaces perpendicular to the thickness direction of the insulating layer 10 and constitute front and back surfaces of the insulating layer 10. The second main surface 10b is a surface opposite to the first main surface 10a. The thickness of the insulating layer 10 is defined as a thickness T1. The thickness T1 is, for example, 12.5 μm to 100 μm. The thickness T1 is an average of values measured at any ten points on a cross-sectional photograph.

The constituent material of the first copper layer 11 is copper or a copper alloy. The first copper layer 11 is disposed on the first main surface 10a. The constituent material of the second copper layer 12 is copper or a copper alloy. The second copper layer 12 is disposed on the second main surface 10b.

A through-hole 13 is formed in the insulating layer 10 and the first copper layer 11. The through-hole 13 extends through the insulating layer 10 and the first copper layer 11 in the thickness direction. The shape of the through-hole 13 in plan view is, for example, a circular shape. However, the planar shape of the through-hole 13 is not limited to this. The opening diameter of the through-hole 13, for example, decreases toward the second main surface 10b. The width of the through-hole 13 at the first main surface 10a is defined as a width W1. The second copper layer 12 is exposed from the through-hole 13. The width W1 is, for example, 25 μm to 250 μm.

The constituent material of the third copper layer 20 is copper or a copper alloy. The third copper layer 20 may be a copper layer formed by electroplating (copper electroplating layer). A single copper layer is disposed on an inner wall surface of the through-hole 13. Herein, the single copper layer is the third copper layer 20. The expression “a single copper layer is disposed on an inner wall surface of the through-hole 13” means that two or more copper layers are not continuously stacked on an inner wall surface of the through-hole 13. In other words, on the inner wall surface of the through-hole 13, for example, a resin layer or an adhesive layer is formed on a surface of the third copper layer 20 on the opposite side from the inner wall surface. Alternatively, a layer made of a metal other than copper is stacked on the surface of the third copper layer 20 on the opposite side from the inner wall surface.

The third copper layer 20 is disposed on the second copper layer 12 exposed inside the through-hole 13, on the inner wall surface of the through-hole 13, and on the first copper layer 11 located around the through-hole 13. Herein, the expression “the third copper layer 20 is disposed on the first copper layer 11 located around the through-hole 13” means that the third copper layer 20 is disposed on a side surface of the first copper layer 11 constituting the through-hole 13 and disposed on at least a portion of an upper surface of the first copper layer 11 (a surface opposite to the surface in contact with the first main surface 10a). Since the third copper layer 20 is disposed on at least a portion of the upper surface of the first copper layer 11, the separation of the third copper layer 20 from the insulating layer 10 (through-hole 13) can be suppressed by the anchoring effect. The third copper layer 20 is also disposed on the first copper layer 11 located in a portion other than the portion around the through-hole 13. The third copper layer 20 constitutes a wiring line of the printed wiring board 100. The wiring line of the printed wiring board 100 is electrically connected to the second copper layer 12 exposed inside the through-hole 13.

The thickness of the third copper layer 20 located on the first copper layer 11 is defined as a thickness T2. The thickness T2 may be equal to or more than 0.4 times the thickness T1, and equal to or less than 0.6 times the width W1. The thickness T2 is an average of values measured at any ten points on a cross-sectional photograph. The thickness T2 may be equal to or more than 0.8 times the thickness T1, and equal to or less than 0.45 times the width W1. The thickness T2 is, for example, 10 μm to 45 μm. Herein, the width W1 is the minimum value of the width of the through-hole 13 at the first main surface 10a. The “minimum value of the width of the through-hole 13 at the first main surface 10a” refers to the diameter of a circle inscribed in the shape of the through-hole 13 in plan view on the first main surface 10a.

At the interface between the insulating layer 10 constituting the inner wall surface of the through-hole 13 and the third copper layer 20 and the interface between the second copper layer 12 and the third copper layer 20, no palladium is present or palladium that is unintentionally mixed in a plating layer bath adheres unavoidably. That is, the palladium concentration in a region of the third copper layer 20 from the interface between the insulating layer 10 (inner wall surface of the through-hole 13) and the third copper layer 20 to a depth of 10 nm is 0.5% by mass or less. Furthermore, the palladium concentration in a region of the third copper layer 20 from the interface between the second copper layer 12 exposed inside the through-hole 13 and the third copper layer 20 to a depth of 10 nm is 0.5% by mass or less. No palladium is present also at the interface between the first copper layer 11 and the third copper layer 20, and the palladium concentration in a region of the third copper layer 20 from the interface between the first copper layer 11 and the third copper layer 20 to a depth of 10 nm is 0.5% by mass or less. The palladium concentration in a region of the third copper layer 20 is measured by, for example, energy dispersive X-ray spectroscopy on a cross section cut through a hole portion by a focused ion beam.

### <Method of Manufacturing Printed Wiring Board 100>

A method of manufacturing a printed wiring board 100 will be described below.

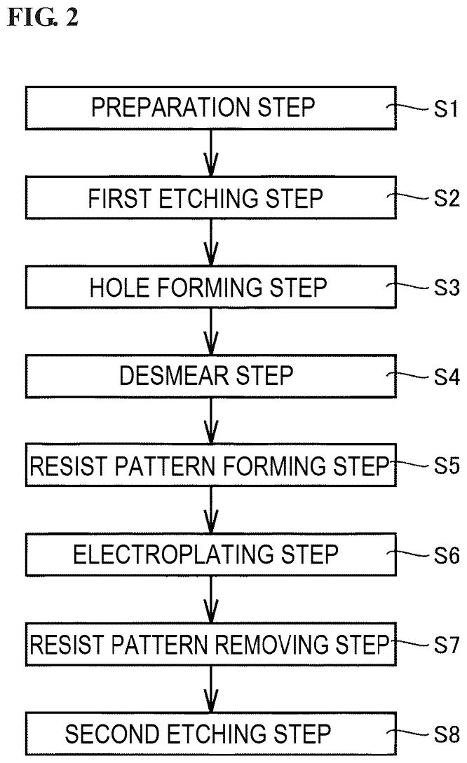

FIG. 2 is a flowchart illustrating a process of manufacturing the printed wiring board 100. As illustrated in FIG. 2, the method of manufacturing the printed wiring board 100 includes a preparation step S1, a first etching step S2, a hole forming step S3, a desmear step S4, a resist pattern forming step S5, an electroplating step S6, a resist pattern removing step S7, and a second etching step S8.

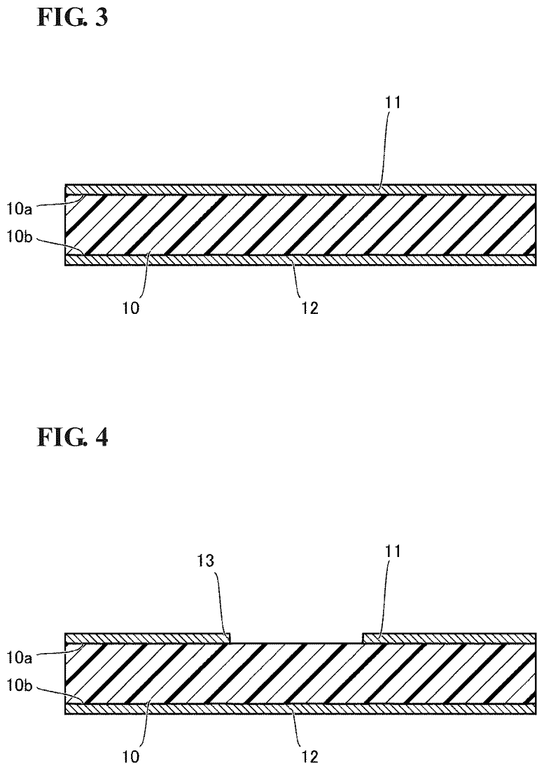

FIG. 3 is a sectional view illustrating the preparation step S1. As illustrated in FIG. 3, in the preparation step S1, an insulating layer 10 is prepared. In the insulating layer 10 prepared in the preparation step S1, a first copper layer 11 is disposed over the entire surface of a first main surface 10a, and a second copper layer 12 is disposed over the entire surface of a second main surface 10b. The insulating layer 10 prepared in the preparation step S1 does not have a through-hole 13.

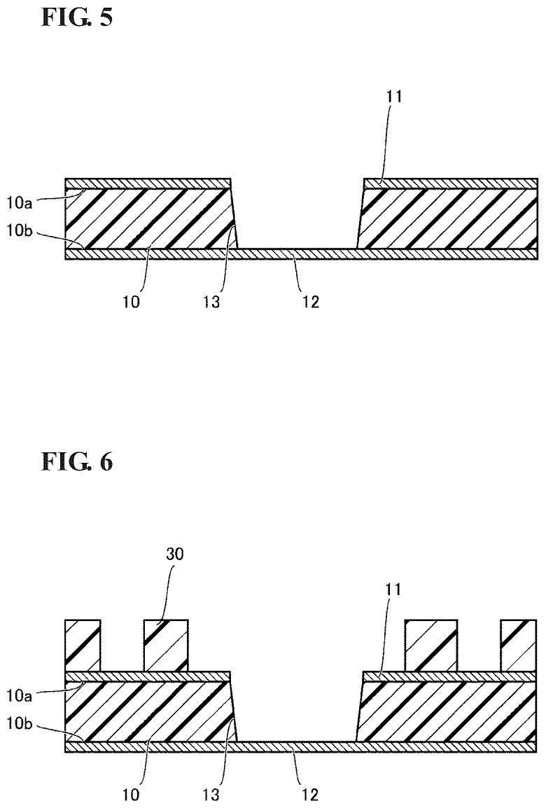

The first etching step S2 is performed after the preparation step S1. FIG. 4 is a sectional view illustrating the first etching step S2. As illustrated in FIG. 4, in the first etching step S2, a portion of the through-hole 13 provided in the first copper layer 11 is formed by etching. The hole forming step S3 is performed after the first etching step S2. FIG. 5 is a sectional view illustrating the hole forming step S3. As illustrated in FIG. 5, a portion of the through-hole 13 provided in the insulating layer 10 is formed by, for example, irradiation with a laser beam.

The desmear step S4 is performed after the hole forming step S3. In the desmear step S4, foreign matter and the like on the surface of the second copper layer 12 exposed inside the through-hole 13 are removed by etching.

The resist pattern forming step S5 is performed after the desmear step S4. The etching in the desmear step S4 is mildly performed so as not to excessively erode the second copper layer 12 exposed inside the through-hole 13. Thus, after the desmear step S4 is performed but before the resist pattern forming step S5 is performed, foreign matter and the like may remain on the surface of the second copper layer 12 exposed inside the through-hole 13.

FIG. 6 is a sectional view illustrating the resist pattern forming step S5. As illustrated in FIG. 6, in the resist pattern forming step S5, a resist pattern 30 is formed. The resist pattern 30 is formed by, for example, attaching a dry film resist onto the first copper layer 11, and exposing and developing the attached dry film resist. Since the development of the dry film resist is performed using an alkali-based solution, part of the foreign matter and the like remaining on the surface of the second copper layer 12 exposed inside the through-hole 13 is removed at this time.

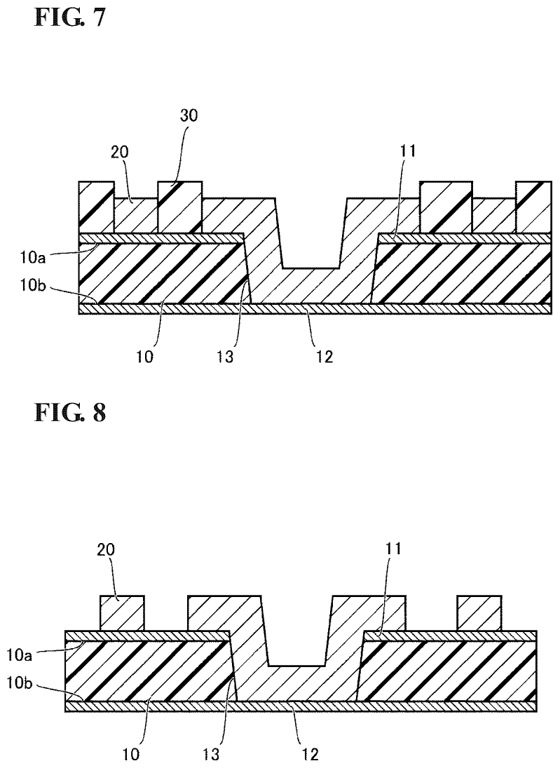

The electroplating step S6 is performed after the resist pattern forming step S5. FIG. 7 is a sectional view illustrating the electroplating step S6. As illustrated in FIG. 7, in the electroplating step S6, a third copper layer 20 is formed by electroplating on the first copper layer 11 exposed from the opening of the resist pattern 30 and on the second copper layer 12 exposed inside the through-hole 13.

The third copper layer 20 on the first copper layer 11 located around the through-hole 13 extends along the inner wall surface of the through-hole 13 as the growth proceeds. The third copper layer 20 on the second copper layer 12 exposed insides the through-hole 13 also extends along the inner wall surface of the through-hole 13 as the growth proceeds. Thus, the third copper layer 20 extending along the inner wall surface of the through-hole 13 from above the first copper layer 11 located around the through-hole 13 and the third copper layer 20 extending along the inner wall surface of the through-hole 13 from above the second copper layer 12 exposed inside the through-hole 13 are integrated together, and consequently, the third copper layer 20 is also formed on the inner wall surface of the through-hole 13.

Note that, after the resist pattern forming step S5 is performed but before the electroplating step S6 is performed, a degreasing treatment is performed. This further removes foreign matter and the like remaining on the surface of the second copper layer 12 exposed inside the through-hole 13.

The resist pattern removing step S7 is performed after the electroplating step S6. FIG. 8 is a sectional view illustrating the resist pattern removing step S7. As illustrated in FIG. 8, in the resist pattern removing step S7, the resist pattern 30 is removed. The second etching step S8 is performed after the resist pattern removing step S7. In the second etching step S8, the first copper layer 11 located under the resist pattern 30 is removed. Thus, the printed wiring board 100 having the structure illustrated in FIG. 1 is formed.

### <Advantageous Effects of Printed Wiring Board 100>

Advantageous effects of the printed wiring board 100 will be described below in comparison with a comparative example. A printed wiring board according to a comparative example is referred to as a printed wiring board 100A.

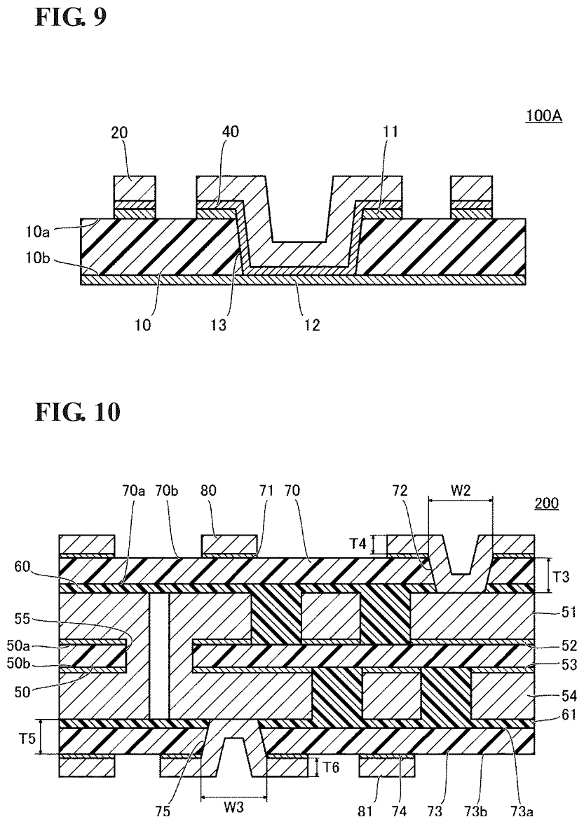

FIG. 9 is a sectional view of the printed wiring board 100A. As illustrated in FIG. 9, the printed wiring board 100A further includes an electroless copper plating layer 40. The electroless copper plating layer 40 is a copper layer formed by electroless plating. The electroless copper plating layer 40 is disposed on a first copper layer 11, on an inner wall surface of a through-hole 13, and on a second copper layer 12 exposed inside the through-hole 13. The configuration of the printed wiring board 100A is common to the configuration of the printed wiring board 100 except for these points.

A method of manufacturing the printed wiring board 100A further includes an electroless plating step S9. The electroless plating step S9 is performed after the desmear step S4 is performed but before the resist pattern forming step S5 is performed. In the electroless plating step S9, a palladium catalyst is applied on the first copper layer 11, on the inner wall surface of the through-hole 13, and on the second copper layer 12 exposed inside the through-hole 13, and electroless plating is then performed to thereby form an electroless copper plating layer 40.

In the method of manufacturing the printed wiring board 100A, in the resist pattern forming step S5, a resist pattern 30 is formed on the electroless copper plating layer 40 located on the first copper layer 11. In the method of manufacturing the printed wiring board 100A, in the electroplating step S6, a third copper layer 20 is formed on the electroless copper plating layer 40. In the method of manufacturing the printed wiring board 100A, in the second etching step S8, the electroless copper plating layer 40 and the first copper layer 11 that are located under the resist pattern 30 are removed. The method of manufacturing the printed wiring board 100A is common to the method of manufacturing the printed wiring board 100 except for these points.

Since the method of manufacturing the printed wiring board 100A includes the electroless plating step S9, palladium remains at the interface between the insulating layer 10 (inner wall surface of the through-hole 13) and the electroless copper plating layer 40 and the interface between the second copper layer 12 exposed inside the through-hole 13 and the electroless copper plating layer 40.

In addition, after the desmear step S4 is performed, foreign matter and the like may remain on the surface of the second copper layer 12 exposed inside the through-hole 13; therefore, foreign matter and the like may remain between the second copper layer 12 exposed inside the through-hole 13 and the electroless copper plating layer 40. In the method of manufacturing the printed wiring board 100A, when the resist pattern forming step S5 and the electroplating step S6 are performed, the second copper layer 12 exposed inside the through-hole 13 is covered with the electroless copper plating layer 40; therefore, the foreign matter and the like are not removed by the development in the resist pattern forming step S5 and the degreasing treatment before the electroplating step S6.

The palladium remaining at the interface between the insulating layer 10 (inner wall surface of the through-hole 13) and the electroless copper plating layer 40 and the interface between the second copper layer 12 exposed inside the through-hole 13 and the electroless copper plating layer 40, and the foreign matter and the like between the second copper layer 12 exposed inside the through-hole 13 and the electroless copper plating layer 40 may cause the separation of the third copper layer 20 together with the electroless copper plating layer 40, resulting in disconnection.

In the method of manufacturing the printed wiring board 100, since the electroless plating step S9 is not performed, palladium does not remain at the interface between the insulating layer 10 (inner wall surface of the through-hole 13) and the third copper layer 20 and the interface between the second copper layer 12 exposed inside the through-hole 13 and the third copper layer 20. Moreover, in the method of manufacturing the printed wiring board 100, foreign matter and the like on the second copper layer 12 exposed inside the through-hole 13 are removed by the development in the resist pattern forming step S5 and the degreasing treatment before the electroplating step S6 is performed. Thus, the printed wiring board 100 can reduce the occurrence of disconnection in a blind via hole caused by the separation of the third copper layer 20 due to, for example, palladium, foreign matter, and the like.

If the thickness T2 is less than 0.4 times the thickness T1, the growth of the third copper layer 20 is insufficient, and the third copper layer 20 extending along the inner wall surface of the through-hole 13 from above the first copper layer 11 around the through-hole 13 is less likely to be connected to the third copper layer 20 extending along the inner wall surface of the through-hole 13 from above the second copper layer 12 exposed inside the through-hole 13. If the thickness T2 exceeds 0.6 times the width W1, the third copper layer on the first copper layer 11 located around the through-hole 13 covers the top of the through-hole 13, and the growth of third copper layer 20 on the second copper layer 12 exposed inside the through-hole 13 may be insufficient.

Thus, when the thickness T2 is equal to or more than 0.4 times the thickness T1 and is equal to or less than 0.6 times the width W1, the third copper layer 20 extending along the inner wall surface of the through-hole 13 from above the first copper layer 11 located around the through-hole 13 is likely to be connected to the third copper layer 20 extending along the inner wall surface of the through-hole 13 from above the second copper layer 12 exposed inside the through-hole 13, and the third copper layer 20 can be appropriately formed on the inner wall surface of the through-hole 13.

### EXAMPLES

To evaluate the effect of the thickness T2, samples 1 to 8 are prepared. In samples 1 to 8, the ratio of the thickness T2 to the thickness T1 and the ratio of the thickness T2 to the width W1 are changed. Details of samples 1 to 8 are described in Table 1. In sample 1, sample 2, and samples 4 to 6, the thickness T2 is equal to or more than 0.4 times the thickness T1 and is equal to or less than 0.6 times the width W1. On the other hand, in sample 3, the thickness T2 is less than 0.4 times the thickness T1 and exceeds 0.6 times the width W1. In sample 7, the thickness T2 is less than 0.4 times the thickness T1. In sample 8, the thickness T2 exceeds 0.6 times the width W1.

TABLE 1

| Sample | 1 | 2 | 3 | 4 | 5 | 6 | 7 | 8 |
|---|---|---|---|---|---|---|---|---|
| Thickness T1 (μm) | 12.5 | 25 | 125 | 100 | 25 | 35 | 100 | 25 |
| Thickness T2 (μm) | 10 | 45 | 45 | 45 | 45 | 20 | 20 | 45 |
| Width W1 (μm) | 25 | 100 | 70 | 250 | 80 | 50 | 50 | 50 |
| Thickness T2/Thickness T1 | 0.8 | 1.8 | 0.36 | 0.45 | 1.8 | 0.57 | 0.2 | 1.8 |
| Thickness T2/Width W1 | 0.4 | 0.45 | 0.64 | 0.18 | 0.56 | 0.4 | 0.4 | 0.9 |
| Defect rate (%) | 0 | 0 | 100 | 12 | 17 | 33 | 100 | 100 |

For samples 1 to 8, the presence or absence of disconnection in the blind via hole is observed. The defect rate in Table 1 is a proportion of blind via holes that are not appropriately formed in each sample. As shown in Table 1, the defect rates in sample 1, sample 2, and samples 4 to 6 are lower than the defect rates in sample 3, and samples 7 and 8.

This comparison revealed that when the thickness T2 is equal to or more than 0.4 times the thickness T1 and is equal to or less than 0.6 times the width W1, the third copper layer 20 extending along the inner wall surface of the through-hole 13 from above the first copper layer 11 located around the through-hole 13 is likely to be connected to the third copper layer 20 extending along the inner wall surface of the through-hole 13 from above the second copper layer 12 exposed inside the through-hole 13, and the third copper layer 20 is likely to be appropriately formed on the inner wall surface of the through-hole 13.

In sample 1, the thickness T2 is equal to or more than 0.8 times the thickness T1, whereas in sample 6, the thickness T2 is equal to or more than 0.4 times and less than 0.8 times the thickness T1. The defect rate in sample 1 is lower than the defect rate in sample 6. In sample 2, the thickness T2 is equal to or less than 0.45 times the width W1, whereas in sample 5, the thickness T2 is more than 0.45 times and equal to or less than 0.6 times the width W1. The defect rate in sample 2 is lower than the defect rate in sample 5.

According to these comparisons, when the condition that the thickness T2 is equal to or more than 0.8 times the thickness T1 or the condition that the thickness T2 is equal to or less than 0.45 times the width W2 is further satisfied, the third copper layer 20 extending along the inner wall surface of the through-hole 13 from above the first copper layer 11 located around the through-hole 13 is more likely to be connected to the third copper layer 20 extending along the inner wall surface of the through-hole 13 from above the second copper layer 12 exposed inside the through-hole 13, and the third copper layer 20 can be more appropriately formed on the inner wall surface of the through-hole 13.

### Second Embodiment

A printed wiring board according to a second embodiment will be described. The printed wiring board according to the second embodiment is referred to as a printed wiring board 200.

### <Configuration of Printed Wiring Board 200>

The configuration of the printed wiring board 200 will be described below.

FIG. 10 is a sectional view of the printed wiring board 200. As illustrated in FIG. 10, the printed wiring board 200 includes a first insulating layer 50, a first copper layer 51, an adhesion layer 60, a second insulating layer 70, a second copper layer 71, and a third copper layer 80.

The constituent material of the first insulating layer 50 has electrical insulating properties and flexibility. The constituent material of the first insulating layer 50 is, for example, a polyimide. However, the constituent material of the first insulating layer 50 is not limited to this. The first insulating layer 50 has a first main surface 50a. The first main surface 50a is a surface perpendicular to the thickness direction of the first insulating layer 50 and constitutes one of front and back surfaces of the first insulating layer 50.

The constituent material of the first copper layer 51 is copper or a copper alloy. The first copper layer 51 is disposed on the first main surface 50a. A fourth copper layer 52 may be disposed between the first copper layer 51 and the first main surface 50a. In this case, the first copper layer 51 is a copper electroplating layer.

The adhesion layer 60 is disposed on the first main surface 50a so as to cover the first copper layer 51 (and the fourth copper layer 52). The constituent material of the adhesion layer 60 is an adhesive. The constituent material of the adhesion layer 60 is, for example, an epoxy-based adhesive.

The constituent material of the second insulating layer 70 has electrical insulating properties and flexibility. The constituent material of the second insulating layer 70 is, for example, a polyimide. However, the constituent material of the second insulating layer 70 is not limited to this. The second insulating layer 70 has a second main surface 70a and a third main surface 70b. The second main surface 70a and the third main surface 70b are surfaces perpendicular to the thickness direction of the second insulating layer 70 and constitute front and back surfaces of the second insulating layer 70. The third main surface 70b is a surface opposite to the second main surface 70a. The second insulating layer 70 is disposed on the adhesion layer 60 such that the second main surface 70a faces the adhesion layer 60.

The constituent material of the second copper layer 71 is copper or a copper alloy. The second copper layer 71 is disposed on the third main surface 70b.

A through-hole 72 is formed in the adhesion layer 60, the second insulating layer 70, and the second copper layer 71. The through-hole 72 extends through the adhesion layer 60, the second insulating layer 70, and the second copper layer 71 in the thickness direction. The first copper layer 51 is exposed from the through-hole 72. The width of the through-hole 72 at the third main surface 70b is defined as a width W2. Herein, the width W2 is the minimum value of the width of the through-hole 72 at the third main surface 70b. The minimum value of the width of the through-hole 72 at the third main surface 70b refers to the diameter of a circle inscribed in the shape of the through-hole 72 in plan view on the third main surface 70b. The width W2 is, for example, 25 μm to 250 μm. The sum of the thickness of the second insulating layer 70 and the thickness of the adhesion layer 60 located between the first copper layer 51 and the second insulating layer 70 is defined as a thickness T3. The thickness T3 is, for example, 12.5 μm to 250 μm. The thickness T3 is an average of values measured at any ten points on a cross-sectional photograph. The shape of the through-hole 72 in plan view is, for example, a circular shape. However, the planar shape of the through-hole 72 is not limited to this.

The third copper layer 80 is disposed on the first copper layer 51 exposed inside the through-hole 72, on the inner wall surface of the through-hole 72, and on the second copper layer 71 located around the through-hole 72. The third copper layer 80 is also disposed on the second copper layer 71 located in a portion other than the portion around the through-hole 72. The constituent material of the third copper layer 80 is copper or a copper alloy. The third copper layer 80 may be a copper electroplating layer.

The palladium concentration in a region of the third copper layer 80 from the interface between the first copper layer 51 exposed inside the through-hole 72 and the third copper layer 80 to a depth of 10 nm is 0.5% by mass or less. The palladium concentration in a region of the third copper layer 80 from the interface between the second insulating layer 70 (inner wall surface of the through-hole 72) and the third copper layer 80 to a depth of 10 nm is 0.5% by mass or less. The palladium concentration in a region of the third copper layer 80 from the interface between the second copper layer 71 and the third copper layer 80 to a depth of 10 nm is 0.5% by mass or less. The palladium concentration in a region of the third copper layer 80 is measured by, for example, energy dispersive X-ray spectroscopy on a cross section cut through a hole portion by a focused ion beam.

The thickness of the third copper layer 80 located on the second copper layer 71 is defined as a thickness T4. The thickness T4 is an average of values measured at any ten points on a cross-sectional photograph. The thickness T4 may be equal to or more than 0.4 times the thickness T3, and equal to or less than 0.6 times the width W2. The thickness T4 may be equal to or more than 0.8 times the thickness T3, and equal to or less than 0.45 times the width W2. The thickness T4 is, for example, 10 μm to 45 μm.

The printed wiring board 200 may further include a fifth copper layer 53, a sixth copper layer 54, an adhesion layer 61, a third insulating layer 73, a seventh copper layer 74, and an eighth copper layer 81. A through-hole 55 may be formed in the first insulating layer 50, the fourth copper layer 52, and the fifth copper layer 53. The through-hole 55 extends through the first insulating layer 50, the fourth copper layer 52, and the fifth copper layer 53 in the thickness direction.

A fourth main surface 50b is a surface perpendicular to the thickness direction of the first insulating layer 50 and is a surface opposite to the first main surface 50a. The fifth copper layer 53 is disposed on the fourth main surface 50b. The constituent material of the fifth copper layer 53 is copper or a copper alloy. The sixth copper layer 54 is disposed on the fifth copper layer 53. The constituent material of the sixth copper layer 54 is copper or a copper alloy. The sixth copper layer 54 is a copper electroplating layer. The first copper layer 51 and the sixth copper layer 54 are connected to each other on the inner wall surface of the through-hole 55.

The adhesion layer 61 is disposed on the fourth main surface 50b so as to cover the fifth copper layer 53 and the sixth copper layer 54. The constituent material of the adhesion layer 61 is an adhesive. The constituent material of the adhesion layer 61 is, for example, an epoxy-based adhesive.

The constituent material of the third insulating layer 73 has electrical insulating properties and flexibility. The constituent material of the third insulating layer 73 is, for example, a polyimide. However, the constituent material of the third insulating layer 73 is not limited to this. The third insulating layer 73 has a fifth main surface 73a and a sixth main surface 73b. The fifth main surface 73a and the sixth main surface 73b are surfaces perpendicular to the thickness direction of the third insulating layer 73 and constitute front and back surfaces of the third insulating layer 73. The sixth main surface 73b is a surface opposite to the fifth main surface 73a. The third insulating layer 73 is disposed on the adhesion layer 61 such that the fifth main surface 73a faces the adhesion layer 61.

The constituent material of the seventh copper layer 74 is copper or a copper alloy. The seventh copper layer 74 is disposed on the sixth main surface 73b.

A through-hole 75 is formed in the adhesion layer 61, the third insulating layer 73, and the seventh copper layer 74. The through-hole 75 extends through the adhesion layer 61, the third insulating layer 73, and the seventh copper layer 74 in the thickness direction. The sixth copper layer 54 is exposed from the through-hole 75. The width of the through-hole 75 at the sixth main surface 73b is defined as a width W3. Herein, the width W3 is the minimum value of the width of the through-hole 75 at the sixth main surface 73b. The “minimum value of the width of the through-hole 75 at the sixth main surface 73b” refers to the diameter of a circle inscribed in the shape of the through-hole 75 in plan view on the sixth main surface 73b. The width W3 is, for example, 25 μm to 250 μm. The sum of the thickness of the third insulating layer 73 and the thickness of the adhesion layer 61 located between the sixth copper layer 54 and the third insulating layer 73 is defined as a thickness T5. The shape of the through-hole 75 in plan view is, for example, a circular shape. However, the planar shape of the through-hole 75 is not limited to this. The thickness T5 is, for example, 12.5 μm to 250 μm. The thickness T5 is an average of values measured at any ten points on a cross-sectional photograph.

The eighth copper layer 81 is disposed on the sixth copper layer 54 exposed inside the through-hole 75, on the inner wall surface of the through-hole 75, and on the seventh copper layer 74 located around the through-hole 75. The eighth copper layer 81 is also disposed on the seventh copper layer 74 located in a portion other than the portion around the through-hole 75. The constituent material of the eighth copper layer 81 is copper or a copper alloy. The eighth copper layer 81 may be a copper electroplating layer.

The thickness of the eighth copper layer 81 located on the seventh copper layer 74 is defined as a thickness T6. The thickness T6 may be equal to or more than 0.4 times the thickness T5, and equal to or less than 0.6 times the width W3. The thickness T6 may be equal to or more than 0.8 times the thickness T5, and equal to or less than 0.45 times the width W3. The thickness T6 is, for example, 10 μm to 45 μm.

The palladium concentration in a region of the eighth copper layer 81 from the interface between the sixth copper layer 54 exposed inside the through-hole 75 and the eighth copper layer 81 to a depth of 10 nm is 0.5% by mass or less. The palladium concentration in a region of the eighth copper layer 81 from the interface between the third insulating layer 73 (inner wall surface of the through-hole 75) and the eighth copper layer 81 to a depth of 10 nm is 0.5% by mass or less. The palladium concentration in a region of the eighth copper layer 81 from the interface between the seventh copper layer 74 and the eighth copper layer 81 to a depth of 10 nm is 0.5% by mass or less. The palladium concentration in a region of the eighth copper layer 81 is measured by, for example, energy dispersive X-ray spectroscopy on a cross section cut through a hole portion by a focused ion beam.

The printed wiring board 200 illustrated in FIG. 10 has circuits formed on both surfaces of the first insulating layer 50 and includes two through-holes (through-holes 72 and 75) connected to the circuits, but the printed wiring board according to the present disclosure is not limited to this. The printed wiring board may have a form in which a plurality of single-sided substrates are combined, and may include circuits formed of two or more layers, three or more layers, or six or more layers.

### <Method of Manufacturing Printed Wiring Board 200>

A method of manufacturing a printed wiring board 200 will be described below.

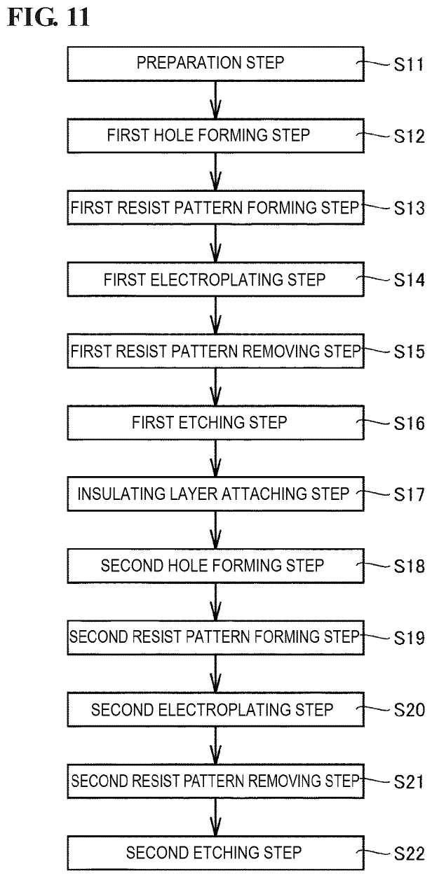

FIG. 11 is a flowchart illustrating a process of manufacturing the printed wiring board 200. As illustrated in FIG. 11, the method of manufacturing the printed wiring board 200 includes a preparation step S11, a first hole forming step S12, a first resist pattern forming step S13, a first electroplating step S14, a first resist pattern removing step S15, and a first etching step S16.

The method of manufacturing the printed wiring board 200 further includes an insulating layer attaching step S17, a second hole forming step S18, a second resist pattern forming step S19, a second electroplating step S20, a second resist pattern removing step S21, and a second etching step S22.

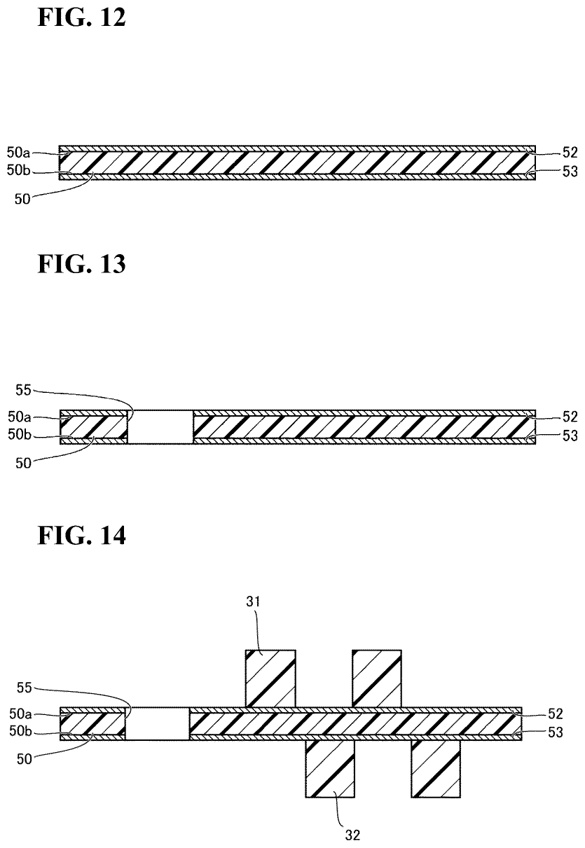

FIG. 12 is a sectional view illustrating the preparation step S11. As illustrated in FIG. 12, in the preparation step S11, a first insulating layer 50 is prepared. In the first insulating layer 50 prepared in the preparation step S11, a fourth copper layer 52 is disposed on a first main surface 50a, and a fifth copper layer 53 is disposed on a fourth main surface 50b. At this time, a through-hole 55 is not formed in the first insulating layer 50, the fourth copper layer 52, and the fifth copper layer 53.

The first hole forming step S12 is performed after the preparation step S11. FIG. 13 is a sectional view illustrating the first hole forming step S12. As illustrated in FIG. 13, in the first hole forming step S12, a through-hole 55 is formed. The through-hole 55 is formed by, for example, irradiation with a laser beam.

The first resist pattern forming step S13 is performed after the first hole forming step S12. FIG. 14 is a sectional view illustrating the first resist pattern forming step S13. As illustrated in FIG. 14, in the first resist pattern forming step S13, a resist pattern 31 is formed on the fourth copper layer 52, and a resist pattern 32 is formed on the fifth copper layer 53. The resist patterns 31 and 32 are each formed by, for example, attaching a dry film resist and exposing and developing the attached dry film resist.

The first electroplating step S14 is performed after the first resist pattern forming step S13. FIG. 15 is a sectional view illustrating the first electroplating step S14. As illustrated in FIG. 15, in the first electroplating step S14, by electroplating, a first copper layer 51 is formed on the fourth copper layer 52 exposed from the opening of the resist pattern 31, and a sixth copper layer 54 is formed on the fifth copper layer 53 exposed from the opening of the resist pattern 32. Furthermore, with the growth of the first copper layer 51 and the sixth copper layer 54, and the first copper layer 51 and the sixth copper layer 54 are connected to each other in the through-hole 55 and integrated together.

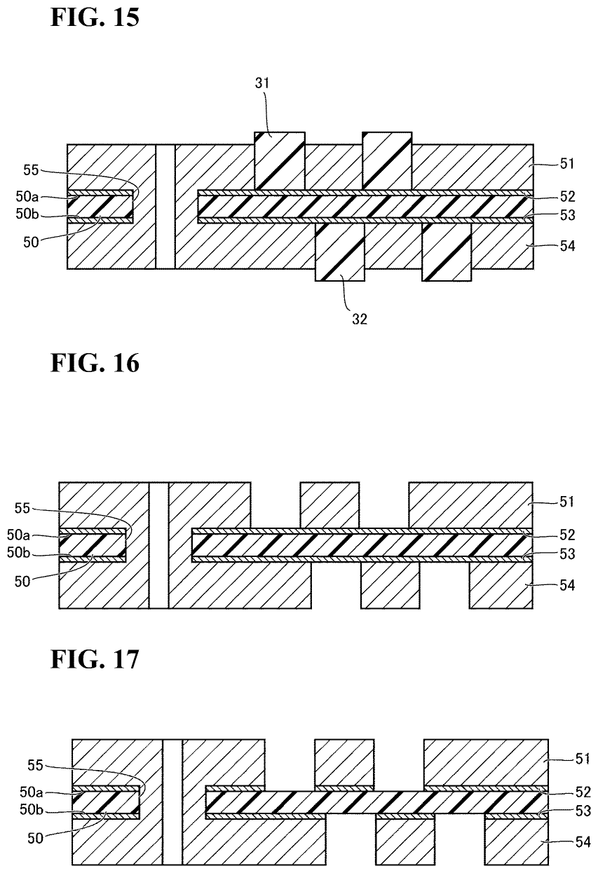

The first resist pattern removing step S15 is performed after the first electroplating step S14. FIG. 16 is a sectional view illustrating the first resist pattern removing step S15. As illustrated in FIG. 16, in the first resist pattern removing step S15, the resist patterns 31 and 32 are removed.

The first etching step S16 is performed after the first resist pattern removing step S15. FIG. 17 is a sectional view illustrating the first etching step S16. As illustrated in FIG. 17, in the first etching step S16, the fourth copper layer 52 located under the resist pattern 31 and the fifth copper layer 53 located under the resist pattern 32 are removed by etching.

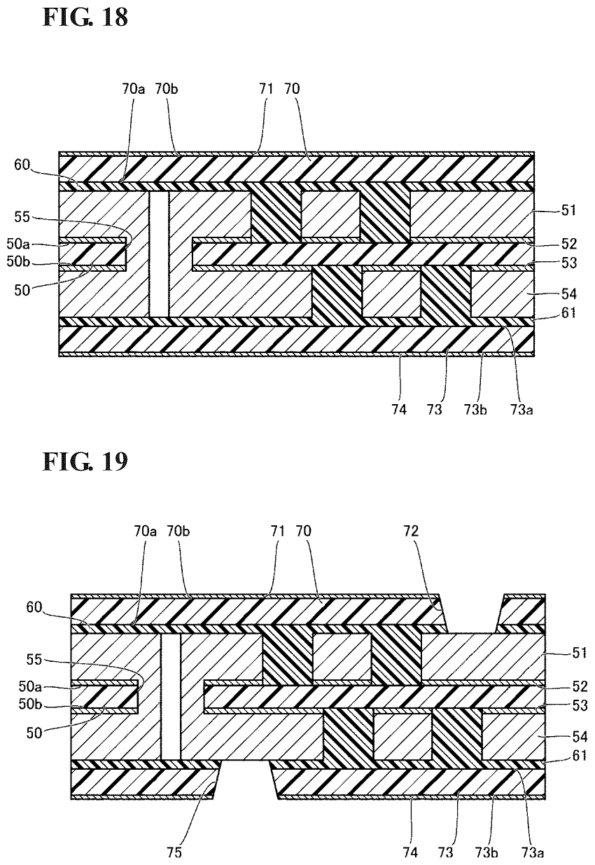

The insulating layer attaching step S17 is performed after the first etching step S16. FIG. 18 is a sectional view illustrating the insulating layer attaching step S17. As illustrated in FIG. 18, in the insulating layer attaching step S17, attachment of a second insulating layer 70 and a third insulating layer 73 is performed. In the insulating layer attaching step S17, first, an uncured adhesion layer 60 is applied to the first main surface 50a so as to cover the first copper layer 51 and the fourth copper layer 52, and an uncured adhesion layer 61 is applied to the fourth main surface 50b so as to cover the fifth copper layer 53 and the sixth copper layer 54. Secondly, a second insulating layer 70 and a third insulating layer 73 are prepared. At this stage, a second copper layer 71 is disposed on a third main surface 70b, and a seventh copper layer 74 is disposed on a sixth main surface 73b.

Thirdly, the second insulating layer 70 is disposed on the adhesion layer 60 such that a second main surface 70a faces the adhesion layer 60, and the third insulating layer 73 is disposed on the adhesion layer 61 such that a fifth main surface 73a faces the adhesion layer 61. Fourthly, the adhesion layers 60 and 61 are cured by heating, and the second insulating layer 70 and the third insulating layer 73 are thereby attached.

The second hole forming step S18 is performed after the insulating layer attaching step S17. FIG. 19 is a sectional view illustrating the second hole forming step S18. As illustrated in FIG. 19, in the second hole forming step S18, through-holes 72 and 75 are formed by, for example, irradiation with a laser beam.

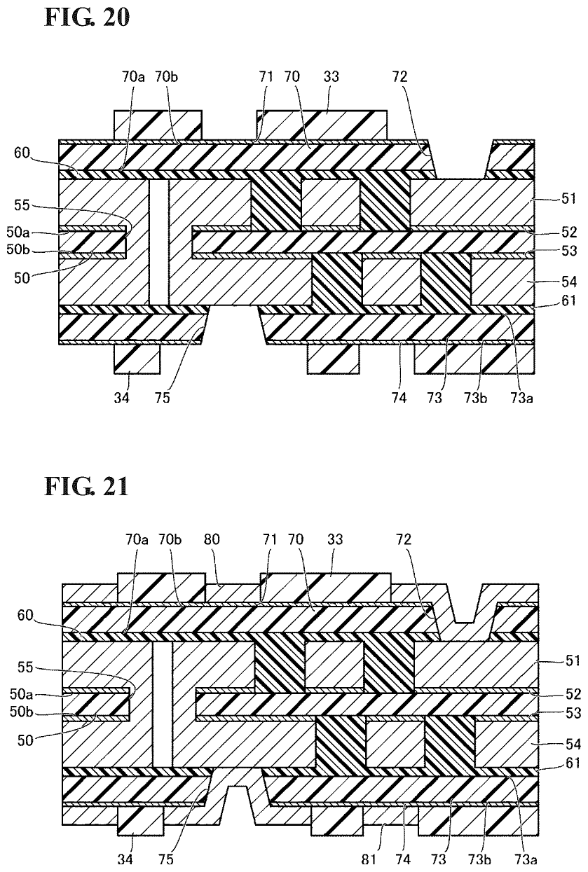

The second resist pattern forming step S19 is performed after the second hole forming step S18. FIG. 20 is a sectional view illustrating the second resist pattern forming step S19. As illustrated in FIG. 20, in the second resist pattern forming step S19, a resist pattern 33 is formed on the second copper layer 71, and a resist pattern 34 is formed on the seventh copper layer 74. The resist patterns 33 and 34 are each formed by, for example, attaching a dry film resist and exposing and developing the attached dry film resist.

The second electroplating step S20 is performed after the second resist pattern forming step S19. FIG. 21 is a sectional view illustrating the second electroplating step S20. As illustrated in FIG. 20, in the second electroplating step S20, by electroplating, a third copper layer 80 is formed on the second copper layer 71 exposed from the opening of the resist pattern 33, on the inner wall surface of the through-hole 72, and on the first copper layer 51 exposed inside the through-hole 72. Furthermore, in the second electroplating step S20, an eighth copper layer 81 is formed on the seventh copper layer 74 exposed from the opening of the resist pattern 34, on the inner wall surface of the through-hole 75, and on the sixth copper layer 54 exposed inside the through-hole 75.

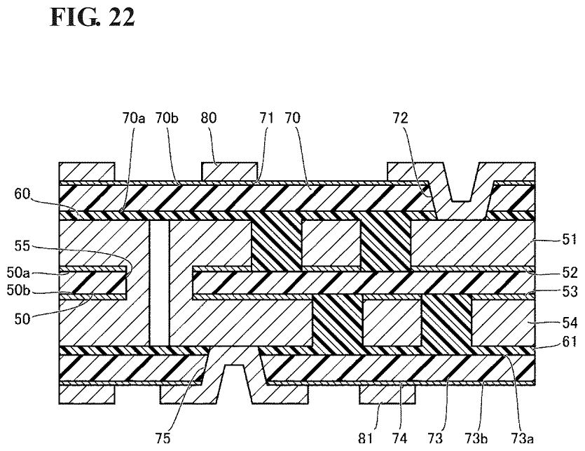

The second resist pattern removing step S21 is performed after the second electroplating step S20. FIG. 22 is a sectional view illustrating the second resist pattern removing step S21. As illustrated in FIG. 22, in the second resist pattern removing step S21, the resist patterns 33 and 34 are removed. The second etching step S22 is performed after the second resist pattern removing step S21. In the second etching step S22, the second copper layer 71 located under the resist pattern 33, and the seventh copper layer 74 located under the resist pattern 34 are removed by etching. Thus, the printed wiring board 200 having the structure illustrated in FIG. 10 is manufactured.

### <Advantageous Effects of Printed Wiring Board 200>

Advantageous effects of the printed wiring board 200 will be described below.

In the method of manufacturing the printed wiring board 200, since an electroless plating step is not performed, palladium does not remain at the interface between the second insulating layer 70 (inner wall surface of the through-hole 72) and the third copper layer 80 and the interface between the first copper layer 51 exposed inside the through-hole 72 and the third copper layer 80. Moreover, in the method of manufacturing the printed wiring board 200, foreign matter and the like on the first copper layer 51 exposed inside the through-hole 72 are removed by the development in the second resist pattern forming step S19 and a degreasing treatment before the second electroplating step S20 is performed.

Thus, the printed wiring board 200 can reduce the occurrence of disconnection in a blind via hole caused by the separation of the third copper layer 80 due to, for example, palladium, foreign matter, and the like. For the same reasons, the printed wiring board 200 can reduce the occurrence of disconnection in a blind via hole caused by the separation of the eighth copper layer 81 due to, for example, palladium, foreign matter, and the like.

It is to be understood that the embodiments disclosed herein are only illustrative and non-restrictive in all respects. The scope of the present invention is defined not by the embodiments described above but by the appended claims and is intended to include all modifications that fall within the scope of the claims and the equivalents thereof.

### REFERENCE SIGNS LIST

10 insulating layer
10a first main surface
10b second main surface
11 first copper layer
12 second copper layer
13 through-hole
20 third copper layer
30, 31, 32, 33, 34 resist pattern
40 electroless copper plating layer
50 first insulating layer
50a first main surface
50b fourth main surface
51 first copper layer
52 fourth copper layer
53 fifth copper layer
54 sixth copper layer
55 through-hole
60, 61 adhesion layer
70 second insulating layer
70a second main surface
70b third main surface
71 second copper layer
72 through-hole
73 third insulating layer
73a fifth main surface
73b sixth main surface
74 seventh copper layer
75 through-hole
80 third copper layer
81 eighth copper layer
100, 100A, 200 printed wiring board
S1 preparation step
S2 first etching step
S3 hole forming step
S4 desmear step
S5 resist pattern forming step
S6 electroplating step
S7 resist pattern removing step
S8 second etching step
S9 electroless plating step
S11 preparation step
S12 first hole forming step
S13 first resist pattern forming step
S14 first electroplating step
S15 first resist pattern removing step
S16 first etching step
S17 insulating layer attaching step
S18 second hole forming step
S19 second resist pattern forming step
S20 second electroplating step
S21 second resist pattern removing step
S22 second etching step
T1, T2, T3, T4, T5, T6 thickness
W1, W2, W3 width

1. A printed wiring board comprising:
an insulating layer having a first main surface and a second main surface;
a first copper layer disposed on the first main surface;
a second copper layer disposed on the second main surface; and
a third copper layer,
wherein a through-hole reaching the second copper layer is formed in the insulating layer and the first copper layer,
the third copper layer is disposed on the second copper layer inside the through-hole, on an inner wall surface of the through-hole, and on the first copper layer located around the through-hole,
a single copper layer is disposed on the inner wall surface of the through-hole, and the single copper layer is the third copper layer.

2. The printed wiring board according to claim 1, wherein a thickness of the third copper layer on the first copper layer is equal to or more than 0.4 times a thickness of the insulating layer and is equal to or less than 0.6 times a minimum value of a width of the through-hole at the first main surface.

3. The printed wiring board according to claim 1, wherein a thickness of the third copper layer on the first copper layer is equal to or more than 0.8 times a thickness of the insulating layer and is equal to or less than 0.45 times a minimum value of a width of the through-hole at the first main surface.

4. The printed wiring board according to claim 1, wherein palladium concentrations in a region of the third copper layer from an interface between the insulating layer and the third copper layer to a depth of 10 nm and a region of the third copper layer from an interface between the second copper layer and the third copper layer to a depth of 10 nm are each 0.5% by mass or less.

5. The printed wiring board according to claim 1, wherein the third copper layer is a copper electroplating layer.

6. A printed wiring board comprising:
a first insulating layer having a first main surface;
a first copper layer disposed on the first main surface;
an adhesion layer disposed on the first main surface so as to cover the first copper layer;
a second insulating layer having a second main surface and a third main surface and disposed on the adhesion layer such that the second main surface faces the adhesion layer;
a second copper layer disposed on the third main surface; and
a third copper layer,
wherein a through-hole reaching the first copper layer is formed in the second insulating layer, the second copper layer, and the adhesion layer,
the third copper layer is disposed on the first copper layer inside the through-hole, on an inner wall surface of the through-hole, and on the second copper layer located around the through-hole,
a single copper layer is disposed on the inner wall surface of the through-hole, and the single copper layer is the third copper layer.

7. The printed wiring board according to claim 6, wherein a thickness of the third copper layer on the second copper layer is equal to or more than 0.4 times a sum of a thickness of the second insulating layer and a thickness of the adhesion layer located between the first copper layer and the second insulating layer and is equal to or less than 0.6 times a minimum value of a width of the through-hole at the third main surface.

8. The printed wiring board according to claim 6, wherein a thickness of the third copper layer on the second copper layer is equal to or more than 0.8 times a sum of a thickness of the second insulating layer and a thickness of the adhesion layer located between the first copper layer and the second insulating layer and is equal to or less than 0.45 times a minimum value of a width of the through-hole at the third main surface.

9. The printed wiring board according to claim 6, wherein palladium concentrations in a region of the third copper layer from an interface between the second insulating layer and the third copper layer to a depth of 10 nm and a region of the third copper layer from an interface between the first copper layer and the third copper layer to a depth of 10 nm are each 0.5% by mass or less.

10. The printed wiring board according to claim 6, wherein the third copper layer is a copper electroplating layer.
